(19) United States
(12) Patent Application Publication
(10) Pub. No.: US 2022/0301886 A1
(43) Pub. Date: Sep. 22, 2022

(54) Method for Thermally Spraying Conductor Paths, and Electronic Module

(71) Applicant: Siemens Aktiengesellschaft, München (DE)

(72) Inventors: Oliver Raab, Ortenburg (DE); Stefan Stegmeier, München (DE)

(73) Assignee: Siemens Aktiengesellschaft, München (DE)

(21) Appl. No.: 17/629,917

(22) PCT Filed: Jul. 23, 2020
(86) PCT No.: PCT/EP2020/070753

§ 371 Date: Jan. 25, 2022

(30) Foreign Application Priority Data
Jul. 26, 2019 (DE) 10 2019 211 161.0
Sep. 2, 2019 (DE) 10 2019 213 241.3

(51) Int. Cl. H01L 21/3205; C23C 4/08; C23C 4/134; H01L 21/321; C23C 4/18

(52) U.S. Cl. CPC H01L 21/32051; C23C 4/08; C23C 4/134; H01L 21/321; C23C 4/18

(57) ABSTRACT

A method for fabricating a conductor track, the method comprising:
applying a first metallic and electrically conductive material to form the conductor track; and
spraying a second metallic material on the conductor track; wherein the second metallic material has a lower melting point than the first material.

### CROSS-REFERENCE TO RELATED APPLICATIONS

This application is a U.S. National Stage Application of International Application No. PCT/EP2020/070753 filed Jul. 23, 2020, which designates the United States of America, and claims priority to DE Application No. 10 2019 213 241.3 filed Sep. 2, 2019 and DE Application No. 10 2019 211 161.0 filed Jul. 26, 2019, the contents of which are hereby incorporated by reference in their entirety.

### TECHNICAL FIELD

The present disclosure relates to electronics. Various embodiments of the teachings herein may include methods for thermally spraying conductor tracks comprising metallic material and/or electronic modules.

### BACKGROUND

A new type of construction and joining technology in the manufacture of electronic modules includes thermal spraying of conductor tracks comprising copper or another metallic material on an insulating layer of such electronic modules. Semiconductor components of the electronic module can be contacted electrically by means of thermally sprayed conductor tracks. Sprayed conductor tracks can thus in principle replace conventionally manufactured wire bonds, tape bonds or electrolytically deposited copper structures of electronic modules.

However, the thermal spraying of, in particular, conductor tracks comprising copper requires high process temperatures in order to achieve a satisfactory electrical conductivity of the conductor tracks. These high process temperatures can degrade insulating layers of a power module or even damage semiconductor components of the power module.

### SUMMARY

The teachings of the present disclosure include improved methods for thermally spraying conductor tracks comprising metallic material onto an insulating layer, in particular of an electronic module, which should not impair an insulating layer or other constituents of the electronic module. For example, some embodiments of the teachings herein include a method for thermally spraying at least one conductor track (20) comprising a first metallic and electrically conductive material (40), wherein the at least one conductor track is sprayed additionally with at least one second metallic material (50) which has a lower melting point than the first material (40).

In some embodiments, the first material (40) comprises copper and/or aluminum and/or gold and/or silver and/or titanium and/or nickel and/or molybdenum.

In some embodiments, the second material (50) comprises tin and/or aluminum and/or gold and/or silver.

In some embodiments, the second material (50) has a melting point of not more than 800 degrees Celsius, not more than 300 degrees Celsius, or not more than 150 degrees Celsius.

In some embodiments, particles (240) which have a core (250) comprising the first material (40) and a layer (260) which comprises the second material and coats, e.g. completely coats, the core (250) are employed.

In some embodiments, particles which have a spatter-like shape are employed.

In some embodiments, the second material (320) and the first material (330) are deposited alternately over time.

In some embodiments, the second material (50) is deposited first and the first material (40) is subsequently deposited.

In some embodiments, the first material and the second material are heated after the first material and the second material have been sprayed.

As another example, some embodiments include an electronic module comprising at least one conductor track (20), wherein the conductor track (20) comprises a first electrically conductive material (40) and additionally comprises a second metallic material (50), where the second material (50) has a lower melting point than the first material (40) and where the first material (40) and the second material (50) are interdiffused, in particular alloyed and/or mixed, with one another.

In some embodiments, the at least one conductor track (20) comprises islands formed by the first material (40).

In some embodiments, the electronic module is a power module (10, 200, 300).

In some embodiments, there is at least one power component, in particular semiconductor component, which is contacted by means of the at least one conductor track.

### BRIEF DESCRIPTION OF THE DRAWINGS

The teachings of the present disclosure are illustrated in further detail below with the aid of a working example depicted in the drawing. In the drawing:

FIG. 1 shows, schematically in cross section, a first working example of a method for manufacturing a first working example of an electronic module incorporating teachings of the present disclosure;

FIG. 2 shows, schematically in cross section, a second working example of a method for manufacturing a second working example of an electronic module incorporating teachings of the present disclosure; and

FIG. 3 shows, schematically in cross section, a third working example of a method for manufacturing a third working example of an electronic module incorporating teachings of the present disclosure.

### DETAILED DESCRIPTION

In the embodiments described herein, at least one conductor track is not formed solely by thermal spraying of a single, first, metallic and electrically conductive material, but instead the first material is combined with at least one second material which has a lower melting point than the first material.

Owing to the lower temperature required for thermal spraying, it is possible to manufacture conductor tracks with significantly lower thermal stress of a periphery of the at least one conductor track. In particular, an insulating layer which is optionally provided or a substrate on which the at least one conductor track is formed can be subjected to significantly lower thermal stress. Consequently, the at least one conductor track can be manufactured so that one or more constituents, for instance of an electronic module which is made using the at least one conductor track are degraded to a lesser degree or not at all and in particular a semiconductor component of an electronic module is not damaged or not appreciably damaged. Owing to the low process temperature which can be employed, a greater variety of insulation materials compared to the prior art can be used for the insulating layers. The choice of insulation materials is consequently not restricted by high particle temperatures of the first material.

In particular, the low melting point of the second material makes it possible to utilize interdiffusion processes, so that intermetallic phases of first and second material can be made at particularly low temperature. In this way, significantly lower particle temperatures compared to the first material and at the same time significantly higher electrical conductivity of the conductor track compared to the second material can be realized. In some embodiments, the manufacture of conductor tracks on substrates and therefore also the manufacture of power modules is thus possible with particular reliability.

In this process, the second material functions to a certain extent as adhesive between the particles of the first material. In the case of copper as first material and tin as second material, the melting point of tin is at significantly lower temperatures than that of copper, namely 232° C. compared to 1085° C. This difference between the melting points allows the plasma temperature, and thus the temperature of the particles overall, to be decreased significantly. It is only necessary for the first material, for instance tin, to be present in the liquid phase or in the vapor phase and the temperature of the particles of the second material, for instance copper particles, to be varied within wide limits, depending on the desired properties of the layers to be produced.

In some embodiments, the first material and the second material can be heated after the first material and the second material have been sprayed. In this way, first material and second material can diffuse into one another.

Very strong and crack-inhibiting intermetallic phase crystallites can be realized. In addition, voids in the first material can be avoided. This is because a particularly low porosity and consequently a high layer quality and as a result a particularly high electrical conductivity can be achieved because of the lower temperature.

In some embodiments, high-melting metal layers which at the same time have a high thermal stability can be manufactured as conductor tracks. The conductor tracks are thus firstly easy to make and secondly at the same time particularly thermally stable. Furthermore, the methods taught herein opens up additional degrees of freedom for the manufacture of conductor tracks.

In some embodiments, the first material comprises copper and/or aluminum and/or gold and/or silver and/or titanium and/or nickel and/or molybdenum and/or another metal. In some embodiments, the first material is copper or aluminum or gold or silver or titanium or nickel or molybdenum or another metal.

In some embodiments, the second material comprises tin and/or aluminum and/or another metal. The second material may be tin or aluminum or another metal. Tin and/or aluminum have a sufficiently low melting point compared to typical conductor track materials.

In some embodiments, the second material has a melting point of not more than 900 degrees Celsius, not more than 400 degrees Celsius, not more than 300 degrees Celsius, and/or not more than 250 degrees Celsius. In these embodiments, thermal stressing of the substrate can be limited to not more than the abovementioned temperature threshold values and thus to significantly lower temperature values compared to conventional conductor track materials because of the lower melting point of the second material compared to the first material. Degradation of the substrate or of other elements bound to the conductor track can thus be avoided.

In some embodiments, particles which have a core comprising the first material and a layer comprising the second material which coats, e.g., completely coats, the core are employed. Metallic interdiffusion of first and second materials can occur particularly efficiently in this way since first and second materials are already arranged close to one another on the spatial scale of the particle dimensions.

In some embodiments, the second material and the first material are advantageously deposited alternately over time. In this embodiment of the invention, too, first and second materials are sufficiently close to one another on a size scale of alternately deposited layers of first and second material for interdiffusion of first and second materials to be able to occur particularly efficiently.

In some embodiments, the second material may be deposited first and the first material being deposited subsequently. In this way, the second material can be deposited with a temperature which is sufficient for the second material and consequently lower than that required for the first material alone. First material can then be deposited on a layer of second material deposited in this way and joins to the second material by means of interdiffusion as mixture or alloy even at the lower melting point of the second material.

In some embodiments, there is at least one conductor track, the conductor track comprises a first electrically conductive material and in addition at least one second metallic material where the second material has a lower melting point than the first material and where the first and second materials are interdiffused, in particular alloyed and/or mixed, with one another.

In some embodiments, the at least one conductor track comprises islands formed by the first material.

In some embodiments, the electronic module comprises a power module with at least one power component, in particular semiconductor component, which is contacted by means of the at least one conductor track.

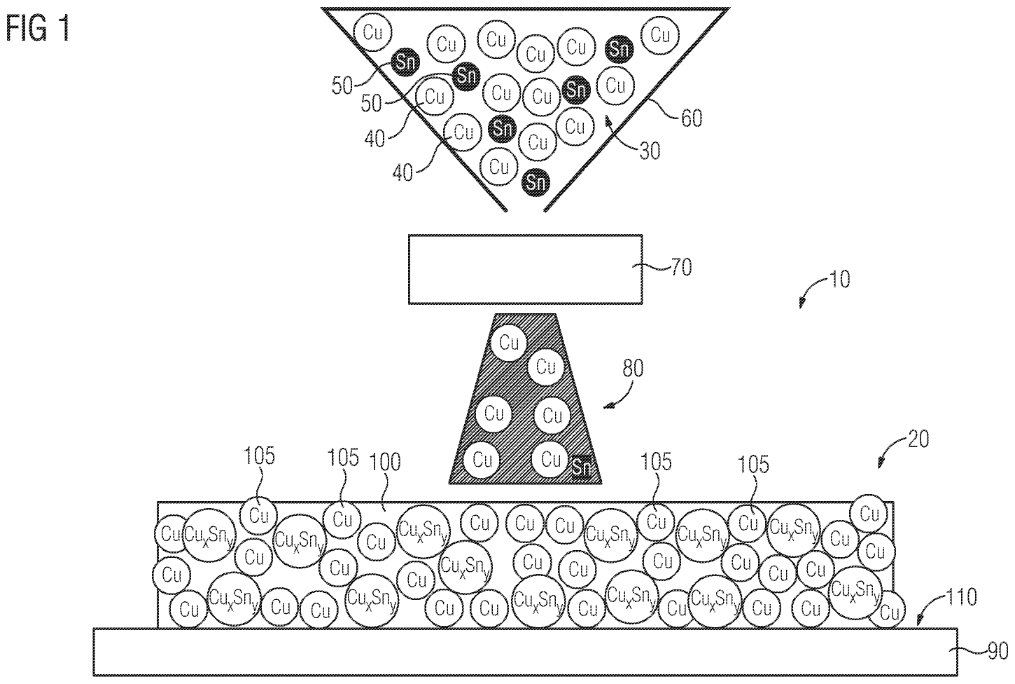

The electronic module depicted in FIG. 1 is a power module 10 and is provided, using a method as described herein, with a conductor track 20 comprising copper which electrically contacts semiconductor components of the power module 10 which are not explicitly depicted. In the manufacturing step depicted, the conductor track 20 is formed by thermal spraying of a particle mixture 30 which comprises homogeneously mixed copper particles 40 and tin particles 50. Here, copper forms the first material and tin forms the second material. In further working examples, the first metallic material can in principle comprise another metal and the second metallic material can in each case comprise a different metal, with the second metallic material having a lower melting point than the first material.

The copper particles 40 and the tin particles 50 have a size, i.e. a diameter, in the range from 5 to 50 microns. The copper particles 40 and the tin particles 50 may be kept in stock as particle mixture 30 in a powder feed device 60 and are fed to a plasma nozzle 70. The plasma nozzle 70 converts the particle mixture 30 into a plasma 80 having a temperature of 200° C.-20,000° C., which heats the particle mixture to a temperature of at least 200 degrees Celsius and not more than 1000 degrees Celsius. At the plasma temperature indicated, the tin becomes liquid, depending on the contact time of the tin particles 50, while the copper particles 40 remain by contrast in the solid state.

In principle, a higher particle temperature, for example 800 degrees Celsius, at which the copper particles 40 predominantly remain in a solid state and are at most partially melted while the tin of the tin particles 50 partly goes over, by contrast already, into the vapor phase can also be selected in the method taught herein.

The plasma 80 impinges on a substrate 90 which has been tempered by means of a heated substrate holder and is deposited there as layer 100. An interdiffusion process of the tin of the tin particles 50 and of the copper of the copper particles 40 occurs both in the plasma 80 and on the substrate 90. Such an interdiffusion process is also known, for example, from diffusion soldering and leads to stable intermetallic phases in the layer 100.

The main proportion of the volume of the layer 100 continues to be made up of copper islands which result from the copper particles 40 and in which the copper is present in virtually pure form, i.e. without proportions of tin which have diffused in. The interdiffusion process ends either when all tin particles 50 have participated in the interdiffusion process, so that no further tin particles 50 are available, or when the diffusion distance for the tin atoms becomes too great or when the thermal treatment is interrupted. The interdiffusion process can also be achieved subsequently by an additional hot aging step (e.g. in an oven).

The composition of the layer 100 can be set via the composition of the particle mixture 30. In further working examples which are not depicted individually, further alloying elements such as silicon and/or silver and/or lead can in principle be additionally added. In further working examples which are not depicted individually, the copper particles 40 are not merely partially melted but also melted completely. In further working examples which are not shown, the copper particles 40 are completely unmelted, but rather the copper particles 40 are entirely present as solid.

The layer 100 is structured along the surface 110 of the substrate 90 by means of masks which are not individually shown or by means of suitable structuring of the surface of the substrate 90 in such a way that the layer 100 forms the conductor track 20 running along the surface 110 of the substrate 90.

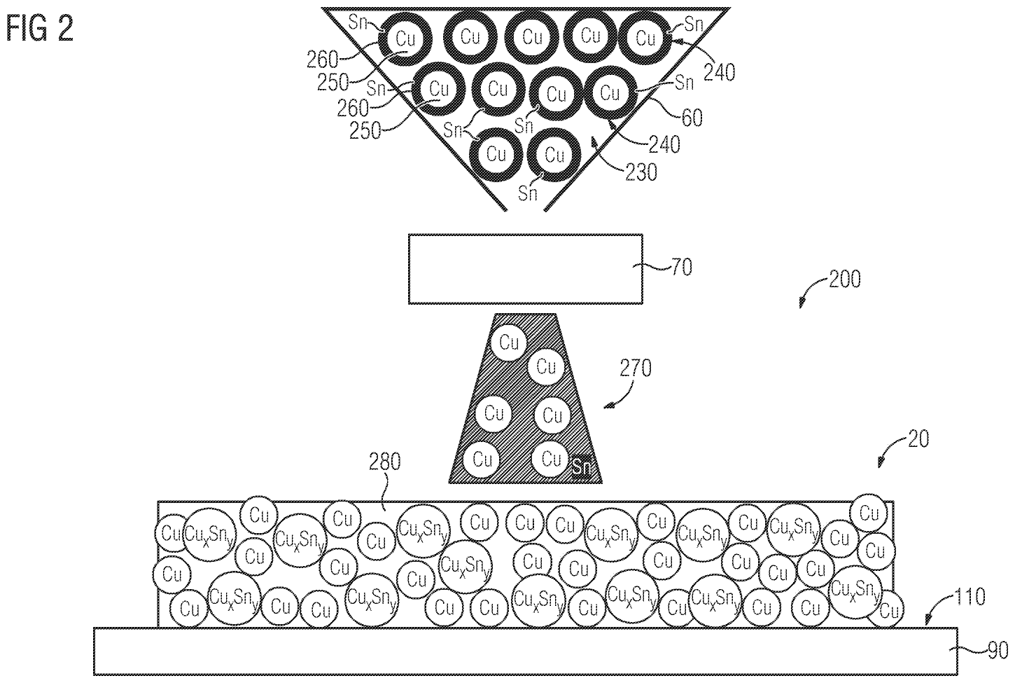

The working example depicted in FIG. 2 corresponds essentially to the working example depicted in FIG. 1 except where indicated otherwise below. Instead of the particle mixture 30, a plurality 230 of identical particles in the form of composite particles 240 is employed in the method depicted in FIG. 2 for manufacturing a power module 200. The composite particles 240 of the plurality 230 have a core-shell structure. In this core-shell structure, a virtually spherical copper particle 250 forms the core of the composite particle 240.

In some embodiments, the copper particle 250 does not have to be spherical but can instead also have any other shape, for example elliptically elongated or elongated in a rod-like manner or shaped as polyhedron. This copper particle 250 is covered by a tin layer 260 which in the working example shown completely surrounds and completely covers the copper particle 250. In further working examples which otherwise correspond to the working example presented, the tin layer 260 at least partly covers the surface of the copper particle 250. “Spatter-like” shapes in which Cu and Sn are present next to one another and thus do not enclose one another are also conceivable.

The ratio of the thickness of the tin layer 260 to the diameter of the copper particle 250 determines the proportion by volume of the tin and of the copper of the plurality 230 of composite particles 240 and thus the proportion by volume of tin and copper in a layer 280 deposited on the substrate 90.

As in the working example described with the aid of FIG. 1, the composite particles 240 are converted into a plasma 270 by means of the plasma nozzle 70, with the tin layer 260 being brought into the liquid phase or into the vapor phase. The copper particles 250, on the other hand, are at most partially melted or remain in the solid state. The plasma 270 is, as described with the aid of FIG. 1, deposited as layer 280 on the substrate 90. Also in the working example of FIG. 2, copper and tin are subjected to an interdiffusion process. In this working example, too, further alloying elements can optionally also be added to the plasma.

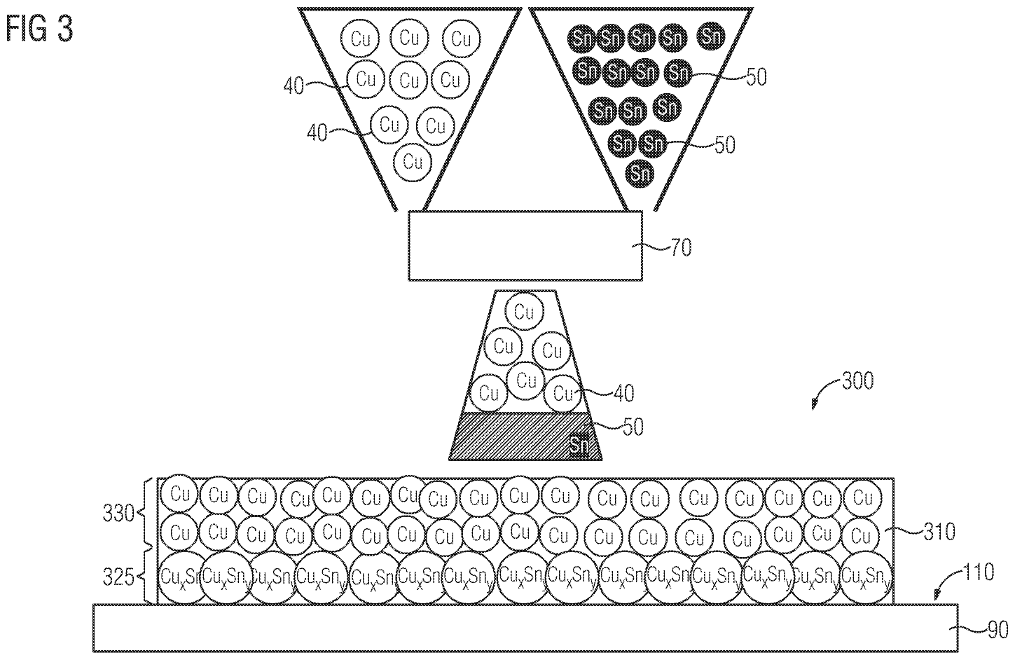

In the working example depicted in FIG. 3, the power module 300 is produced by depositing the layer 310 in alternating sublayers of copper and tin on the substrate 90. For this purpose, a thin tin layer 325 is, for example, firstly deposited on the substrate 90 by means of the tin particles 50 which have been converted into a plasma by the plasma nozzle 70. Owing to the lower melting point of tin compared to copper, this can be carried out at lower temperatures than in the case of copper, for instance at a particle temperature of about 223 degrees Celsius.

Hot copper particles 40 are subsequently converted into a plasma and a hot copper layer 330 is deposited by means of the copper particles 40. The tin layer 325 initially protects the substrate 90 from the thermal impact of the copper particles 40. After application to the tin layer 325, the copper of the copper particles 40 and the tin of the tin particles 50 diffuse into one another so as to form a stable intermetallic phase. In the working example depicted, the alternate deposition of tin and copper is optionally repeated one or more times. In some embodiments, only a continued thermal spraying of copper can also occur. In the working example depicted in FIG. 3, too, the main proportion of the electrical conductivity is brought about by the pure regions of the copper layer 330.

In all the working examples described above, the interdiffusion process can also be carried out after spraying. For example, the layers 100, 280, 325, 330 can be thermally treated subsequently, for example in a temperature range from 200 degrees Celsius to 500 degrees Celsius. The intermetallic CuSn phases can thus be formed during the thermal treatment which can, for example, continue for a few minutes or a number of hours. The intermetallic phase is preferably formed as Cu₃Sn and Cu₆Sn₅.

Furthermore, the CuSn system should be regarded merely as representative of diffusion solder materials. In general, many further metal systems, for instance silver and/or gold and/or aluminum and/or titanium and/or nickel and/or one or more other metal(s), including combinations, are possible.

What is claimed is:

1. A method for fabricating a conductor track, the method comprising:
applying a first material to form the conductor track, wherein the first material comprises a metallic and electrically conductive material; and
spraying a second metallic material on the conductor track;
wherein the second metallic material has a lower melting point than the first material.

2. The method as claimed in claim 1, wherein the first material comprises at least one metal selected from the group consisting of: copper, aluminum, gold, silver, titanium, nickel, and molybdenum.

3. The method as claimed in claim 1, wherein the second material comprises at least one metal selected from the group consisting of: tin, aluminum, gold, and silver.

4. The method as claimed in claim 1, wherein the second material has a melting point of not more than 800 degrees Celsius.

5. A method for fabricating a conductor track, the method comprising:
applying particles to form the conductor track;
wherein each particle includes a core comprising a first material and a coating comprising a second material;
wherein the second metallic material has a lower melting point than the first material.

6. The method as claimed in claim 1, wherein at least one of the first material and the second material comprises particles with a spatter-like shape.

7. The method as claimed in claim 1, further comprising applying the second material and the first material alternately over time.

8. The method as claimed in claim 7, further comprising depositing the second material first; and
depositing and the first material subsequently.

9. The method as claimed in claim 1, further comprising heating the first material and the second material after both the first material and the second material have been sprayed.

10. An electronic module comprising:
a conductor track comprising a first electrically conductive material and a second metallic material;
wherein the second material has a lower melting point than the first material;
the first material and the second material are interdiffused with one another.

11. (canceled)

12. The electronic module as claimed in claim 10, wherein the conductor track comprises islands formed by the first material.

13. (canceled)

14. The electronic module as claimed in claim 10, further comprising a power component electrically contacted by the conductor track.
